(19) United States
(12) Patent Application Publication
(10) Pub. No.: US 2026/0292968 A1
(43) Pub. Date: Sep. 24, 2026

(54) COOLING SYSTEM

(71) Applicant: Infineon Technologies Austria AG, Villach (AT)

(72) Inventor: Veljko Palija, Röthenbach a.d. Pegnitz (DE)

(21) Appl. No.: 19/571,759

(22) Filed: Mar. 19, 2026

(30) Foreign Application Priority Data
Mar. 19, 2025 (DE) 102025110663.0

(51) Int. Cl. H05K 1/02

(52) U.S. Cl. CPC H05K 1/0203

(57) ABSTRACT

A cooling system includes: a heatsink having a base portion and a heat exchanger portion coupled to a first surface of the base portion; a spring element; and a frame. The frame includes a first frame surface with at least one opening for accommodating the heatsink. The opening includes a stepped portion at an inner sidewall of the opening. The stepped portion is configured to receive the spring element and the first surface of the base portion.

### TECHNICAL FIELD

The present disclosure relates to a cooling system comprising a heatsink.

### BACKGROUND

In many applications of electronic power systems with top side cooled components, large common heatsinks are used. Large heatsinks however impose many challenges related to mechanical stress, thermal interface, isolation and assembly.

One of the most critical challenges is the planarity of the top side of the components, when more than one component dissipates heat over the common heat sink. As a result, a significant height deviation between components may occur. This requires thick thermal interface materials to be used like gap fillers or gap pads, which however worsens the thermal performance of the devices. Further issues like warpage of Printed Circuit Boards, PCBs, must be considered, particularly when large PCBs are used.

Documents U.S. Pat. Nos. 9,646,910 B2 and 7,269,018 B2 provide an overview over common proposals of the prior art. However, the solutions provided are still complicated, difficult to manufacture and only provide little improvements in terms of thermal performance.

Accordingly, it is an objective of the present disclosure to at least mitigate these shortcomings.

### SUMMARY

According to a first aspect of the present disclosure, a cooling system is provided. The cooling system comprises a heatsink, the heatsink comprising a base portion and a heat exchanger portion coupled to a first surface of the base portion. The cooling system further comprises a spring element and a frame, the frame comprising a first frame surface with at least one opening for accommodating the heatsink, wherein the opening comprises a stepped portion at an inner side wall of the opening, the stepped portion being configured to receive the spring element, and the first surface of the base portion.

The cooling device according to the present disclosure allows incorporating sensitive components, e.g. the housing of an inverter and respective cooling elements like heatsinks, into a compact, common structure.

The frame forms a body to accommodate at least one heatsink or a plurality of heatsinks, i.e. cooling elements, wherein the heatsinks are inserted into the frame. Each heatsink comprises a base portion having a first surface. The first surface of the one or more heatsinks engages with the stepped portion of the inner sidewalls of the openings. An elastic element or a spring element is arranged between the first surface of the heatsink and the stepped portion. The elastic element may be a compressible element which is configured to compensate possible height differences between cooling surfaces of heat dissipating components to be cooled by the cooling device. Moreover, the frame may be an insulating frame and/or may be part of a fluid cooling system.

The frame allows for using separated heatsinks for each sensitive component instead of one large common heatsink. Thermal performance, that is an efficiency of a heat transfer away from the sensitive component, may be enhanced. The frame may be used in various embodiments.

Further, using the frame may result in supporting sustainability through easier repair, refurbishing and recycling. The frame can also be applied to a variety of sensitive components e.g. discrete molded modules, passive components and for power modules.

Still further, the frame may additionally be used for handling and/or storing the heatsinks and the sensitive components during a production process.

In an embodiment, the base portion comprises a second surface opposite the first surface, and the second surface is configured to contact a heat transmitting surface of a heat emitting device.

The sensitive component may be a heat emitting device, which may comprise at least one heat transmitting surface, configured to transfer heat from the device to a heatsink. The heat transmitting surface may be brought into at least thermal contact with the second surface of the heatsink.

In an embodiment, the first surface of the base portion comprises a collar portion, wherein the collar portion is in contact with the spring element when the heatsink is in an inserted position inside the frame.

The base portion may form a collar portion. The collar portion may be configured to interlock and be in contact with the stepped portion at the inner side wall of the opening such that the heatsink engages positively interlocking with the stepped portion in an inserting direction. The collar portion may also be referred to as a circumferential portion of the first surface of the heatsink, wherein the circumferential portion/collar portion circumferentially surrounds at least part of the heat exchanger portion.

In an embodiment, the opening is a through hole and, in the inserted position, the heat exchanger portion of the heatsink protrudes past a second surface of the frame. The heat exchanger portion may protrude past the frame to be in better contact with the cooling fluid for example the surrounding air. The heat exchanger portion may comprise, for example, fins or plates or needles or any protrusions than enable a transfer of thermal energy from the heatsink to a cooling medium.

In an embodiment, the inner sidewall of the at least one opening forms part of a channel, particularly a channel for guiding a cooling fluid past the heat exchanger portion of the heatsink.

In this embodiment, the heat exchanger portion may be at least partially surrounded by at least parts of the inner sidewalls of the openings. The second surface of the frame may be structured such that the openings form channels or trenches through which the cooling medium may flow.

In an embodiment, the frame forms a housing comprising the channel, wherein the channel is leak proof, and wherein the heat exchanger portion protrudes into the channel to be in contact with cooling fluid.

The frame may include liquid tight or leak proof channels, wherein the channels may be formed by extended sidewalls such that the frame forms a complete housing surrounding and hermetically sealing off the channels. In other words, the frame, at the second surface, may also comprise sidewalls which may form a guiding channel for a cooling fluid. The system may hence be applied in a liquid cooling system.

In an embodiment, the system may comprise the heat emitting device, wherein the heat emitting device is mounted onto a panel.

Particularly, the heat emitting device is a semiconductor device or a passive device, and the panel is a Printed Circuit Board, PCB, or an Active Metal Braze substrate, AMB, or a Direct Copper Bond substrate, DCB. The heat emitting device may have a heat transmitting surface, which may be arranged opposite a side of the device facing the panel.

The system may be applied to cool semiconductor devices, particularly a plurality of semiconductor devices wherein each semiconductor device of the plurality of semiconductors is brought into contact, by the frame, with a respective one of the heatsinks, and wherein all the semiconductor devices are mounted to the same panel, as it is common practice in electronic power systems. By virtue of the frame, differences in height of the semiconductor devices with respect to the panel can be levelled by the elasticity of the spring element. For example, a PCB containing top side cooled components may be fixed on top of the frame/carrier so that the heatsinks are pushed by the elastic elements towards the top side cooled components at the PCB. Thereby a stable but flexible connection, particularly a thermal connection, between the heat emitting devices and the heatsinks may be established.

In particular, the panel may be mounted onto the first surface of the frame such that the heat emitting device is inserted into the opening and is in thermal contact with the second surface of the heatsink.

The frame may be further configured to provide additional mechanical support to the panel. In particular, the frame may be stronger and stiffer than the panel, such that when the panel is mounted to the frame, a warpage of the panel may be reduced. Similarly, the panel itself may be lighter, thinner and provide for less mechanical support by itself, which may decrease an amount of material required and decrease a total system cost.

In an embodiment, the spring element is a gasket and hermetically seals a connection between the heatsink and the frame. By providing a sealed connection between the heatsink and the frame, the frame may be used in liquid cooling systems. By the gasket, the heat emitting device, which may be a semiconductor device, is protected from the cooling liquid.

Generally, in the inserted position, the spring element applies a force against the first surface of the heatsink and the second surface of the heatsink is thereby pressed against the heat transmitting surface of the heat emitting device.

Besides the good thermal contact, this further provides the effect that differences in height are outbalanced by the spring element. Hence, a height of each heatsink may be defined independently of one another.

In an embodiment, the frame comprises a plurality of openings wherein each opening is configured to accommodate a respective one of a plurality of heatsinks.

Particularly, the frame may be configured to accommodate a plurality of semiconductor devices and/or passive elements. In other words, a panel, e.g. a PCB, onto which various devices may be mounted, can be matched with the frame and its openings in an upside-down position. Each heat emitting device and the panel may be matched to an individual bespoke heatsink. Therefore, the dimensions of the openings and/or the dimensions of the sidewalls of the openings and/or the dimensions of the stepped portions of the sidewalls, may be configured to individually match the devices at the panel.

In contrast to the prior art, a bulky, large common heatsink is split into multiple units, which are inserted into the specifically arranged openings of the frame/carrier.

Further, the plurality of heatsinks may be galvanically isolated from each other, which may allow to implement the system with a lower level of electrical isolation, in contrast to a large common heatsink.). As a result, thinner thermal interface materials may be used and better thermal contact between heat emitting components and the respective heatsink surface can be achieved.

The frame may be made from any material, but most suitable may be heat resistant, electrically isolating hard plastic. The spring elements can be made in form of a flat spring, or a rubber ring, for example.

In an embodiment, a portion of the frame between two neighboring openings has a width in a range between 10% to 40% of a diameter of the openings.

Particularly, the portion of the frame between the two neighboring openings may also be referred to as a bridge. The bridge may form a mounting portion, that is, a portion of the first frame surface onto which a respective portion of the panel is to be attached in the mounting position. The width of the bridges may also be in a range between 10%-30% of a diameter of the openings or between 10%-20% of a diameter of the openings.

A relatively thick bridge width has the effect that the panel has a good support for being mounted onto the frame which leads to reduced warpage of the panel. The openings of the plurality of openings are separated from one another by the bridges. The bridges form part of the first surface of the frame and are configured to accommodate parts/portions of the panel. The thicker the bridges are, the more contact surface between the panel and the frame is provided. The more contact surface is provided, the better and the more stable is a connection between the panel and the frame in a mounting position. Thus, the thickness of the bridges contributes to a stable connection and a reduction in warpage of the panel, which may occur due to thermal stress and/or mismatches in the coefficient of thermal expansion (CTE). It has been observed that a particularly good stability and low PCB warpage may be achieved, if the width of the bridges is in the above ranges.

In an embodiment, the frame comprises screw domes protruding above the first frame surface and spacing the panel apart from the first frame surface of the frame in a mounting position. The screw domes may space the panel apart from the first surface but may also be in the same plane as the first frame surface, that is, part of the first surface. In this configuration, the second surface of the heatsink and/or the heat emitting devices may also protrude above the first frame surface.

In another embodiment, the frame may not comprise the stepped portion at the inner sidewalls of the openings. In this configuration, the first surface of the heatsink, in particular the collar portion, may be contact with the first frame surface such that the base portion of the heatsink protrudes above the first frame surface. The frame may be further simplified and easier to manufacture. This embodiment may also be combined with the above referenced screw domes, wherein a height of the screw domes above the first frame surface may at least correspond to a thickness of the base portion of the heatsink, preferably correspond to a height of the base portion and possible attached components, such as the semiconductor device and/or a thermal interface material.

In an embodiment, the frame comprises a circumferential portion surrounding the first frame surface, and a height of the circumferential portion corresponds to a thickness of the panel.

The circumferential portion forms a stabilizing frame-like protrusion surrounding the panel. Hence, the panel is fully embedded in the frame. An outer surface of the panel is coplanar with a surface of the circumferential portion.

In an embodiment, the frame comprises a snap-in portion to interlock with the panel in the mounting position, configured to fixedly attach the panel to the frame, and/or wherein the portions of the frame between two neighboring openings comprise further snap-in features configured to protrude through respective openings in the panel and to engage with an outermost surface of the panel.

By virtue of the snap in portions, the production process may be simplified since no screwing or glueing may be needed and the panel and the heat emitting devices which are mounted thereon, are just brought into the mounting position by snapping/clicking the panel into the frame.

In an embodiment, the system comprises a thermal interface material, which is arranged between the second surface of the heatsink and the heat transmitting surface of the heat emitting device. The thermal interface material may be electrically isolating. This may contribute to complete the galvanic isolation of the heatsink. The thermal interface material, which may be of a certain thickness and may have a certain elasticity, may further help to outbalance height differences of the heat emitting devices.

In an embodiment, the sidewall of the opening forms a sealed-off chamber together with the heatsink and the panel. Thereby, the semiconductor device is accommodated inside a chamber of the frame and sealed off against environmental pollution for example. This allows the system to be used in surroundings having a higher pollution degree.

Particularly, the panel may be attached to the frame by gluing or screwing.

### BRIEF DESCRIPTION OF THE DRAWINGS

Exemplary embodiments of the disclosure are described with reference to the following figures:

FIG. 1 shows a frame of an embodiment of the first aspect of the present disclosure.

FIG. 2 shows the frame of FIG. 1 with heatsinks being inserted.

FIG. 3 shows a cross-sectional view of an embodiment of the disclosure.

FIG. 4 shows a cross-sectional view of a further embodiment of the disclosure.

FIG. 5 shows 3D view of the embodiment of FIG. 4.

FIG. 6 shows a further cross-sectional view of the embodiment of FIGS. 4 and 5.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. A semiconductor device as described herein may comprise (doped) semiconductor material and may be a semiconductor chip or be included in a semiconductor chip.

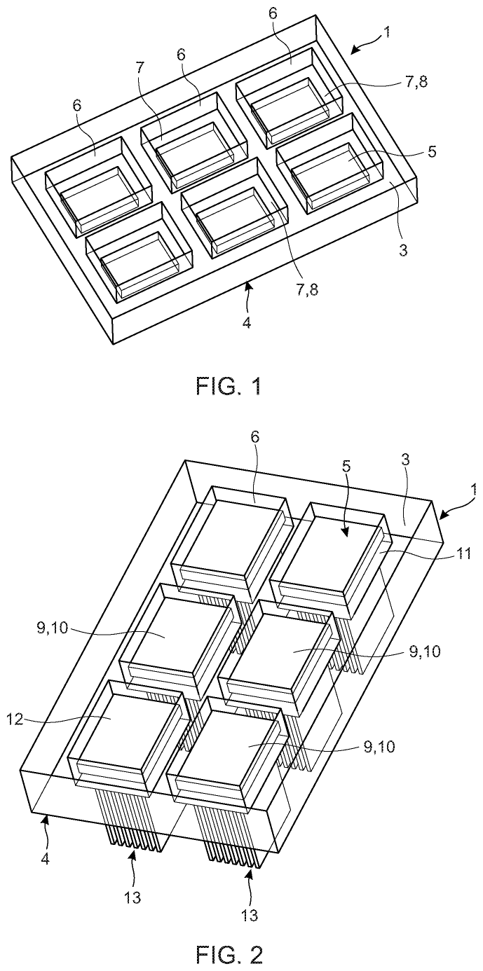

FIG. 1 shows a frame 1 of an embodiment of the system 2 of the present disclosure. The frame 1 comprises a first frame surface 3 and a second side 4 opposite the first frame surface 3. The frame 1 comprises openings 5. In the embodiment of FIG. 1, the frame 1 comprises a plurality of openings 5. The openings 5 form through holes connecting the first frame surface 3 and the second side of the frame 4. Each of the openings 5 comprises an inner sidewall 6. The inner sidewall 6 comprises a stepped portion 7. The stepped portion 7 is a circumferentially protruding portion being part of the inner sidewall 6. The stepped portion 7 provides a supporting surface 8 which is configured to accommodate and be in contact with a device which is to be inserted into the opening 5 of the frame 1.

FIG. 2 shows the frame 1 of FIG. 1 with heatsinks 9 being inserted. The heatsink 9 comprises a base portion 10 having a first surface 11. The first surface 11 of the base portion 10 is, in the inserted position shown in FIG. 2, in contact with the supporting surface 8 of the stepped portion 7. The base portion 10 of the heatsink 9 further comprises a second surface 12.

The second surface 12 of the base portion 10 may be coplanar with the first frame surface 3 in the inserted position, and setback into the frame 1, that is, into the opening 5.

The second surface 12 of the base portion 10 forms contact portion, that is, a contact surface, which may be configured to be in at least thermal contact with the further heat emitting device (not shown), which can also be inserted into the opening 5.

The heatsink 9 further comprises a heat exchanger portion 13. In the inserted position, the heatsinks 9 are inserted into the openings 5 such that the heat exchanger portion 13 protrudes out of the frame 1, that is, past the second side of the frame 4.

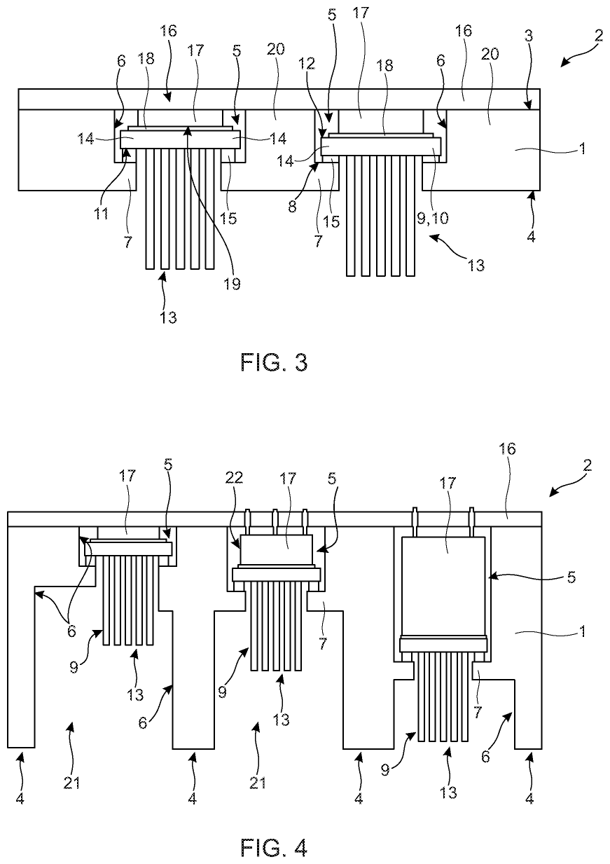

FIG. 3 shows a cross-sectional view of a cooling system 2 according to the disclosure. The heatsinks 9 are inserted into the frame 1 in an upside-down position. In this position, the heat exchanger portion 13 protrudes past the second side of the frame 4. The heat exchanger portion 13 comprises cooling structures, such as fins or ribs.

The base portion 10 of the heatsink 9 comprises a collar portion 14. The collar portion 14 is part of the first surface 11 of the base portion 10, which is in the shown inserted position in contact with the supporting surface 8 of the stepped portion 7. Between the supporting surface 8 of the stepped portion 7 and the first surface 11 of the base portion 10 a spring element 15 is arranged.

The frame 1 is covered by a panel 16, that is, the panel 16 is fixedly attached to the frame 1. Various devices 17, which may be heat emitting devices, are attached to the panel 16. In a mounting position, that is the panel 16 being attached to the first frame surface 3, the devices 17 which are attached to the panel 16 are inserted into the openings 5.

In the mounting position the devices 17 are in thermal contact with the heatsinks 9. To enhance contact or to outbalance possible height differences, a thermal interface material 18 is arranged between the second surface 12 of the base portion 10 and a heat emitting surface of the device 17.

The heat emitting devices 17 may each differ in their height. To established good thermal contact between the heatsink 9 and the device 17 the spring element 15 can be adapted accordingly. Hence, devices 17 having different heights may easily be attached to the same panel 16 and brought into contact, by inserting the devices 17 into the openings 5, with a respective heatsink 9.

A portion of the frame 20 between two neighboring openings 5, which may also be referred to as a bridge, is a support surface for respective portions of the panel 16. The panel is completely coplanar with the first frame surface 3.

The spring element 15 applies a force against the collar portion 14 of the base portion 10 of the heatsink 9 and presses the heatsink with its second surface 12 against the device 17. Hence, in the mounting position, with the panel attached to the frame 1 the spring element 15 is in a compressed state. As a further effect, the spring element 15 may be embodied as a gasket which seals of the connection between the heatsink 9 and frame 1.

It is also conceived that two frames 1 may be mounted onto different sides of one panel 16, that is, a panel 16 may have devices installed thereon on both sides opposite to one another which may be inserted into openings 5 of respective opposite frames 1.

FIG. 4 shows a cross-sectional view of a further embodiment of the cooling system 2. The inner sidewall 6 of the at least one opening 5 forms part of a channel 21, particularly a channel 21 for guiding a cooling fluid past the heat exchanger portion 13 of the heatsink 9. In this embodiment, the heat exchanger portion 13 of the heatsink 9 does not protrude past the second side 4 of the frame 1.

Rather, the heat exchanger portion 13 is enclosed by the frame and merely protrudes into a further portion of the opening opposite the supporting surface 8 of the stepped portion 7. The further portion of the opening may also be referred to as the channel 21.

Further, the sidewall 6 of the opening 5 forms a sealed-off chamber 22 together with the heatsink 9 and the panel 16. A tight connection, that is, a sealed-off connection or a liquid or a fluid proof connection can be established between the first frame surface and the panel 16 by, for example, screwing or glueing.

Devices 17 may have different heights and/or thicknesses. Accordingly, the stepped portion 7 may be in a different vertical position with respect to the panel 16 at the inner sidewall 6 of the opening 5. That is, a distance between the first frame surface 3 and the supporting surface 8 may be adapted according to the height requirements of the device 17 to be inserted into the respective opening 5.

The devices 17 are Surface Mount Devices, SMDs, but may also be a Through-Hole Devices, THDs.

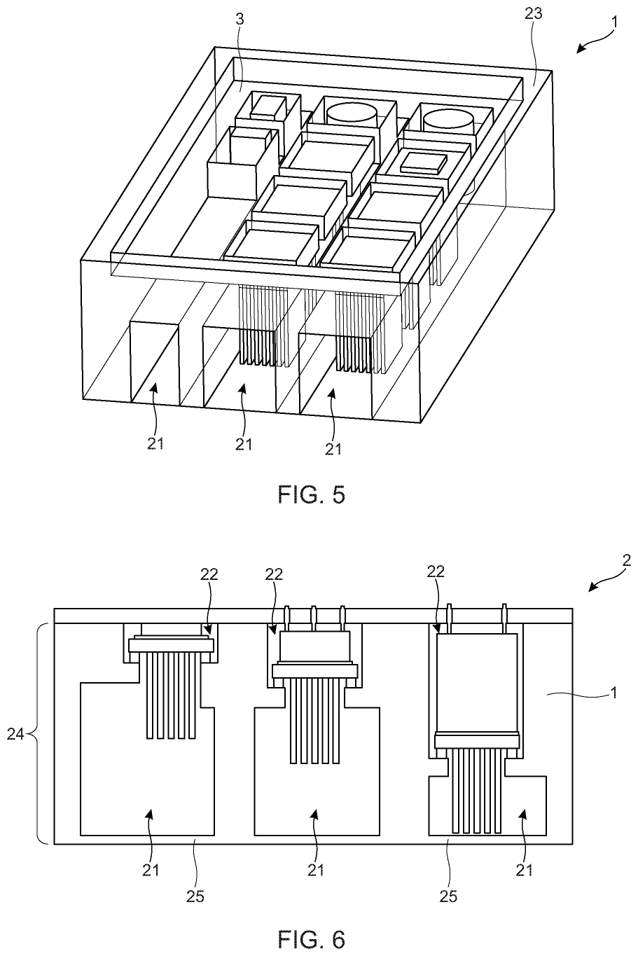

FIG. 5 shows a 3D view of the embodiment of FIG. 4. In addition to FIG. 4, the frame 1 comprises a circumferential portion 23 surrounding the first frame surface 3. The circumferential portion 23 is adapted to surround, that is, match with a dimension of the panel 16 (not shown).

A height of the circumferential portion 23 corresponds to a thickness of the panel 16 (not shown).

FIG. 6 shows a further cross-sectional view of a further embodiment of the present cooling system 2. The frame 1 forms part of a housing 24 comprising the channel 21, and the chamber 22. The housing 24 comprises an integral lower side member 25, closing the channels 21 at the bottom side. The cooling system may hence be also part of a liquid cooling system as liquid can be guided through the channels, which are leakproof.

To transfer heat from the heatsink 9 to the cooling medium, the heat exchanger portion 13 protrudes into the channel 21 to be in contact with the cooling medium, e.g. an isolating fluid or water.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### LIST OF REFERENCE SIGNS

1. Frame
2. system
3. first frame surface
4. second frame side
5. opening
6. inner sidewall
7. stepped portion
8. supporting surface
9. heatsink
10. base portion
11. first surface of the base portion
12. second surface of the base portion
13. heat exchanger portion
14. collar portion
15. spring element
16. panel
17. devices
18. thermal interface material
19. heat emitting surface
20. portion between the openings/bridge
21. channel
22. chamber
23. circumferential portion
24. housing
25. lower side member

What is claimed is:

1. A cooling system, comprising:
a heatsink comprising a base portion and a heat exchanger portion coupled to a first surface of the base portion;
a spring element; and
a frame comprising a first frame surface with at least one opening for accommodating the heatsink, wherein the opening comprises a stepped portion at an inner sidewall of the opening, the stepped portion being configured to receive the spring element and the first surface of the base portion.

2. The cooling system of claim 1, wherein the base portion comprises a second surface opposite the first surface, and wherein the second surface is configured to contact a heat transmitting surface of a heat emitting device.

3. The cooling system of claim 1, wherein the first surface of the base portion comprises a collar portion, and wherein the collar portion is in contact with the spring element when the heatsink is in an inserted position inside the frame.

4. The cooling system of claim 1, wherein the at least one opening is a through hole, and wherein in an inserted position, the heat exchanger portion of the heatsink protrudes past a second surface of the frame.

5. The cooling system of claim 1, wherein the inner sidewall of the at least one opening forms part of a channel configured to guide a cooling fluid past the heat exchanger portion of the heatsink.

6. The cooling system of claim 5, wherein the frame forms part of a housing comprising the channel, wherein the channel is leak proof, and wherein the heat exchanger portion protrudes into the channel to be in contact with a cooling fluid.

7. The cooling system of claim 1, further comprising the heat emitting device, wherein the heat emitting device is mounted onto a panel.

8. The cooling system of claim 7, wherein the heat emitting device is a semiconductor device or a passive device, and wherein the panel is a printed circuit board (PCB), an active metal braze (AMB) substrate, or a direct copper bond (DCB) substrate.

9. The cooling system of claim 7, wherein the panel is mounted onto the first frame surface such that the heat emitting device is inserted into the opening and is in thermal contact with the second surface of the heatsink.

10. The cooling system of claim 7, wherein the frame comprises a plurality of screw domes protruding above the first frame surface in a mounting position.

11. The cooling system of claim 7, wherein the frame comprises a circumferential portion surrounding the first frame surface, and wherein a height of the circumferential portion corresponds to a thickness of the panel.

12. The cooling system of claim 7, wherein the frame comprises a snap-in portion to interlock with the panel in a mounting position, configured to fixedly attach the panel to the frame, and/or wherein portions of the frame between neighboring openings comprise further snap-in features configured to protrude through respective openings in the panel and to engage with an outermost surface of the panel.

13. The cooling system of claim 7, wherein the sidewall of the opening forms a sealed-off chamber together with the heatsink and the panel.

14. The cooling system of claim 1, wherein the spring element is a gasket and hermetically seals a connection between the heatsink and the frame.

15. The cooling system of claim 1, wherein in an inserted position, the spring element applies a force against the first surface of the heatsink such that the first surface of the heatsink is pressed against the heat transmitting surface of the heat emitting device.

16. The cooling system of claim 15, wherein the first surface of the base portion comprises a collar portion, and wherein in the inserted position, the spring element applies the force against the collar portion.

17. The cooling system of claim 1, wherein the frame comprises a plurality of openings, and wherein each opening is configured to accommodate a respective one of a plurality of heatsinks.

18. The cooling system of claim 1, wherein a portion of the frame between two neighboring openings has a minimum width of 50% of a diameter of the openings.

19. The cooling system of claim 1, further comprising a thermal interface material arranged between the second surface of the heatsink and the heat transmitting surface of the heat emitting device.

20. The cooling system of claim 1, wherein the panel is attached to the frame by gluing or screwing.
